(19) United States
(12) Patent Application Publication
(10) Pub. No.: US 2009/0086422 A1
(43) Pub. Date: Apr. 2, 2009

(54) Openable Dual-Board Case for Multi-Mainboard System

(75) Inventors: John McClure, Taipei (TW); Chun-Hung Lee, Taipei (TW)

Correspondence Address: APEX JURIS, PLLC, 12733 LAKE CITY WAY NORTHEAST, SEATTLE, WA, 98125, US

(73) Assignee: TYAN COMPUTER CORPORATION, Taipei (TW)

(21) Appl. No.: 11/627,021

(22) Filed: Jan. 25, 2007

(51) Int. Cl. H05K 7/20; H05K 5/00

(52) U.S. Cl. 361/679.48; 361/679.02

(57) ABSTRACT

An openable dual-board case for multi-mainboard system includes a rectangular tubular body assembled from two bent plates connected together via a pivoting structure, so that the two bent plates are pivotally turnably about the pivoting structure relative to each other to open or close the tubular body. With the openable tubular body, necessary system assembling, dismounting, maintaining, and repairing can be conveniently and efficiently performed. Moreover, two mainboards may be separately mounted on two opposite interiors of the bent plates to face toward each other. Therefore, the openable dual-board case allows a multi-mainboard system to have optimal spatial arrangement to achieve best heat-dissipation efficiency and largely reduce noises.

### BACKGROUND OF THE INVENTION

1. Field of Invention

The present invention relates to a computer case, and more particularly to an openable dual-board case for a multi-mainboard system.

2. Description of the Related Art

With the highly modularized blade architecture, a blade server has the advantages of high density, convenient management, easy expansion, and suitable for special applications. Generally speaking, the blade architecture is one of the best choices for high performance computing (HPC) systems. However, a HPC system produces more heat than general systems while the high density blade architecture reduces the heat-dissipation efficiency. Currently, some of the HPC systems adopt a liquid cooling system that provides high heat-dissipation efficiency. However, when the liquid cooling system provides effectively enhanced heat-dissipation efficiency, it also increases the complication and cost in manufacturing the HPC system.

FIG. 1 shows a conventional personal supercomputer adopting the blade architecture. The personal supercomputer with blade architecture is particularly designed for performing small-scaled but highly complicate computing. As shown in FIG. 1, the personal supercomputer with blade architecture has several mainboards 110 parallelly arranged in a front inner space of a computer case 100. The parallelly arranged mainboards 110 divide the front inner space of the computer case 100 into several sub-spaces to serve as airflow passages, just like common blade architecture. In a rear lower inner space of the computer case 100, a power supply with fan 120 is mounted. And, in a rear upper inner space of the computer case 100, several main fans 130 are mounted to serve as a major cooling airflow source. Airflow 140 sucked into the computer case 100 via a front end thereof passes through each of the sub-spaces and the main fans 130 to finally flow out of the computer case 100 via a rear end thereof.

A big problem with the above-described arrangement is the narrow sub-spaces in the computer case 100 form a big hindrance to good heat dissipation. Meanwhile, noise is produced due to collision of air molecules with different elements mounted in the computer case 100. The spaced narrow airflow passages with uneven surfaces tend to cause more turbulences and louder whooshing sound. For air to smoothly flow in the spaced narrow airflow passages with sufficient air pressure to pass through all small spaces between any two adjacent radiation fins 111 provided on the multiple mainboards 110, small-size fans with high rotary speed must be used. These high-speed small fans also produce high decibel (dB) noise during operation thereof. Moreover, since the multiple mainboards 110 are parallelly spaced in the front inner space of the computer case 100 to face toward the same direction, the radiation fins 111 on each of the mainboards 110 have a length being limited by a distance between two adjacent mainboards 110. In other words, when it is desired to increase the size of fans 130 or the length of radiation fins 111, an overall width of the computer case 100 would inevitably be increased correspondingly. Therefore, it is rather difficult to obtain enhanced heat-dissipation efficiency by increasing the size of the radiation fins 111 in the HPC systems adopting the blade architecture.

Moreover, since the computer case 100 provides a limited internal space, it is uneasy for a user to conveniently mount, dismount, maintain, and/or repair multiple mainboards 110 within such a small space while protecting the computer case 100 and other components mounted therein against impact and damage by tools. Sometimes, the user would even get hurt while handling the mounting, dismounting, maintaining, or repairing of the mainboards 110 in the small computer case 100.

### SUMMARY OF THE INVENTION

It is therefore a primary object of the present invention to provide an openable dual-board case for multi-mainboard system, so that a user may efficiently proceed with system assembling and/or repairing, and the system may have better spatial arrangement to thereby enable optimal heat-dissipation efficiency and largely reduced noise.

To achieve the above and other objects, the openable dual-board case for multi-mainboard system according to the present invention includes a substantially rectangular tubular body, which includes two pivotally connected bent plates to define two open ends.

In a preferred embodiment of the present invention, each of the two bent plate has a first open side and a second open side opposite to each other, and a pivoting side and a joining side opposite to each other. The two open ends defined by the tubular body are separately located at the first and the second open sides of the two bent plates. At least one pivoting structure is provided at the pivoting sides of the two bent plates, so that the two bent plates are pivotally connected by and turnable about the at least one pivoting structure relative to each other to close or open the tubular body.

In another preferred embodiment of the present invention, the tubular body further includes a fastening structure provided at the joining sides of the two bent plates to openably hold the two bent plates in a closed position.

In a further preferred embodiment of the present invention, each of the two bent plates further includes an overlapping section located at the joining side of the bent plate. The overlapping sections on the two bent plates overlap each other when the two bent plates are held to the closed position by the fastening structure. In this case, the fastening structure is located on the overlapping sections.

In a still further preferred embodiment of the present invention, one or more two mainboards are mounted to each of two interiors of the two bent plates that are faced toward each other, so that the mainboards on the interiors of the two bent plates face one another. Each of the mainboards is provided at a position near one open end of the tubular body with one or more processors. The processors on the two facing mainboards are staggered, so that a distance between the interior of each bent plate and a top of radiation fins attached to any processor on the mainboard mounted on that bent plate may be larger than or equal to one half of a distance between the two facing interiors of the two bent plates.

In a preferred embodiment of the present invention, the openable dual-board case for multi-mainboard system further includes at least one cover plate. The cover plate is a substantially rectangular plate for mounting to one of the two open ends of the tubular body. The cover plate is provided with a plurality of fan vents. Cooling fans may be mounted on an interior of the cover plate corresponding to the fan vents to assist in good flowing of cooling airflow.

In a preferred embodiment of the present invention, the tubular body is provided on an exterior of a top and/or a bottom wall with locating rails, which are extended between the two open ends of the tubular body for the openable dual-board case to movably mount to other external mechanisms.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 schematically shows a conventional personal supercomputer with blade architecture;

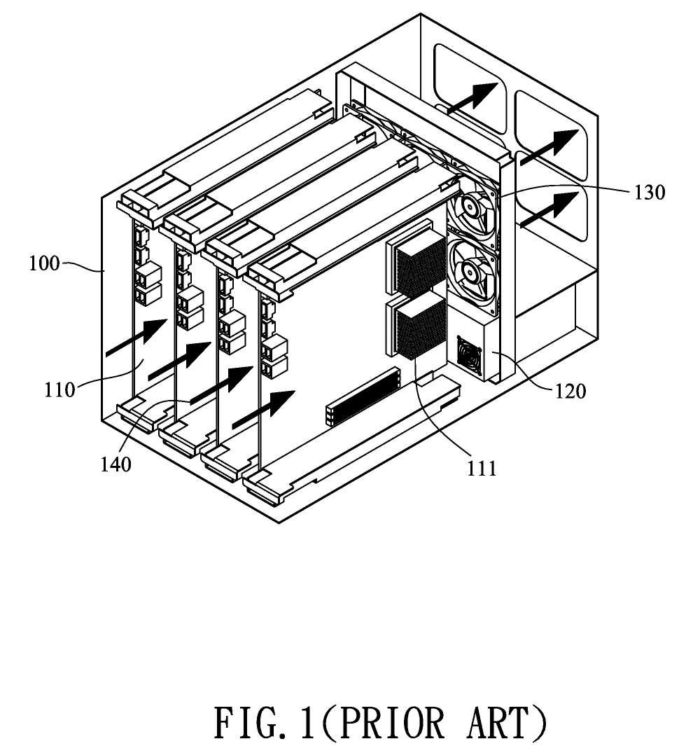

FIG. 2 is an exploded perspective view of an openable dual-board case for multi-mainboard system according to a first embodiment of the present invention;

FIG. 3 is a partially exploded perspective view of an openable dual-board case for multi-mainboard system according to a second embodiment of the present invention;

FIG. 4 is a fragmentary sectional view of the openable dual-board case for multi-mainboard system according to the second embodiment of the present invention;

FIG. 5 is a perspective view of an openable dual-board case for multi-mainboard system according to a third embodiment of the present invention;

FIG. 6 is a perspective view of an openable dual-board case for multi-mainboard system according to a fourth embodiment of the present invention;

FIG. 7 is a partially exploded perspective view of an openable dual-board case for multi-mainboard system according to a fifth embodiment of the present invention;

FIG. 8 shows the mounting of an openable dual-board case according to a sixth embodiment of the present invention into a computer case for a multi-mainboard system;

FIG. 9A is a partially exploded perspective view of an openable dual-board case for multi-mainboard system according to a seventh embodiment of the present invention; and

FIG. 9B is a rear perspective view of a carrier included in the openable dual-board case for multi-mainboard system shown in the seventh embodiment of FIG. 9A.

### DETAILED DESCRIPTION OF THE INVENTION

The present invention is now described with reference to the accompanying drawing, wherein all the reference numerals shown in the specification correspond to those shown in the drawings.

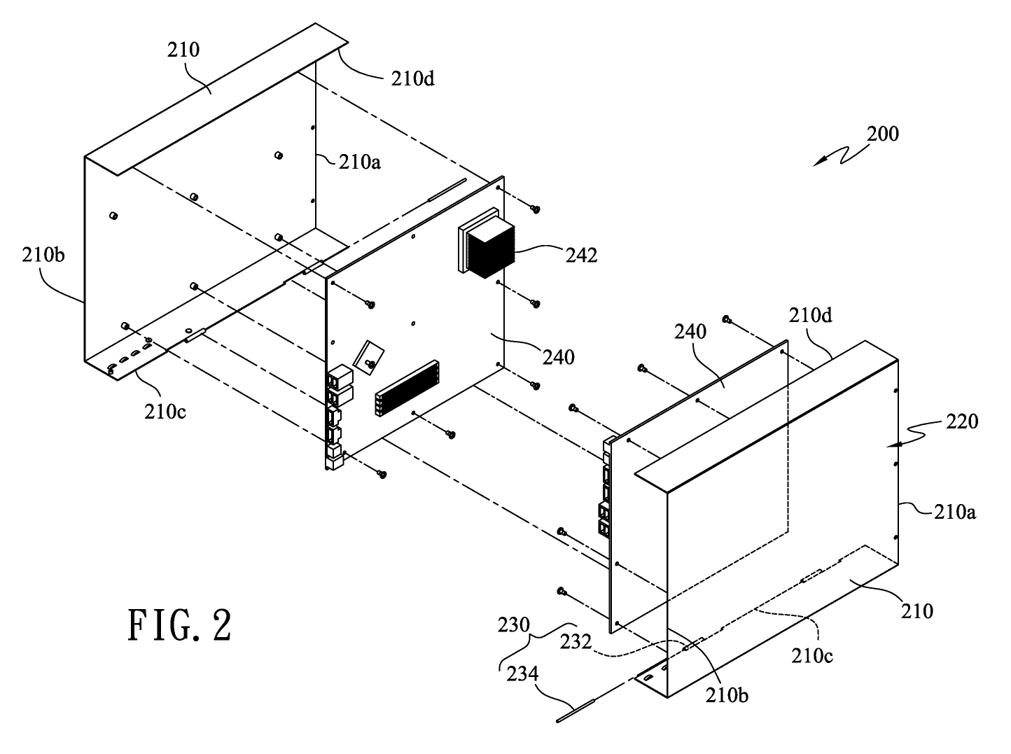

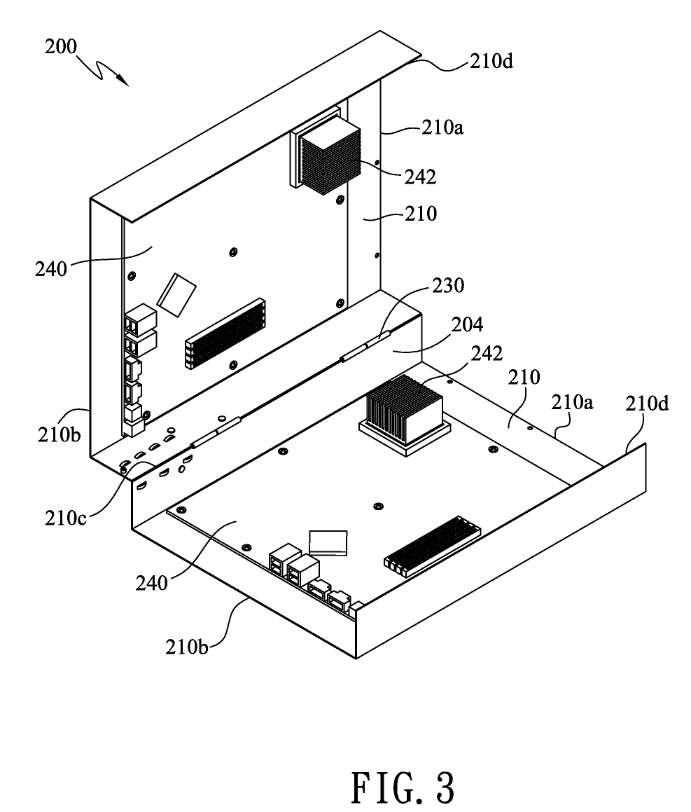

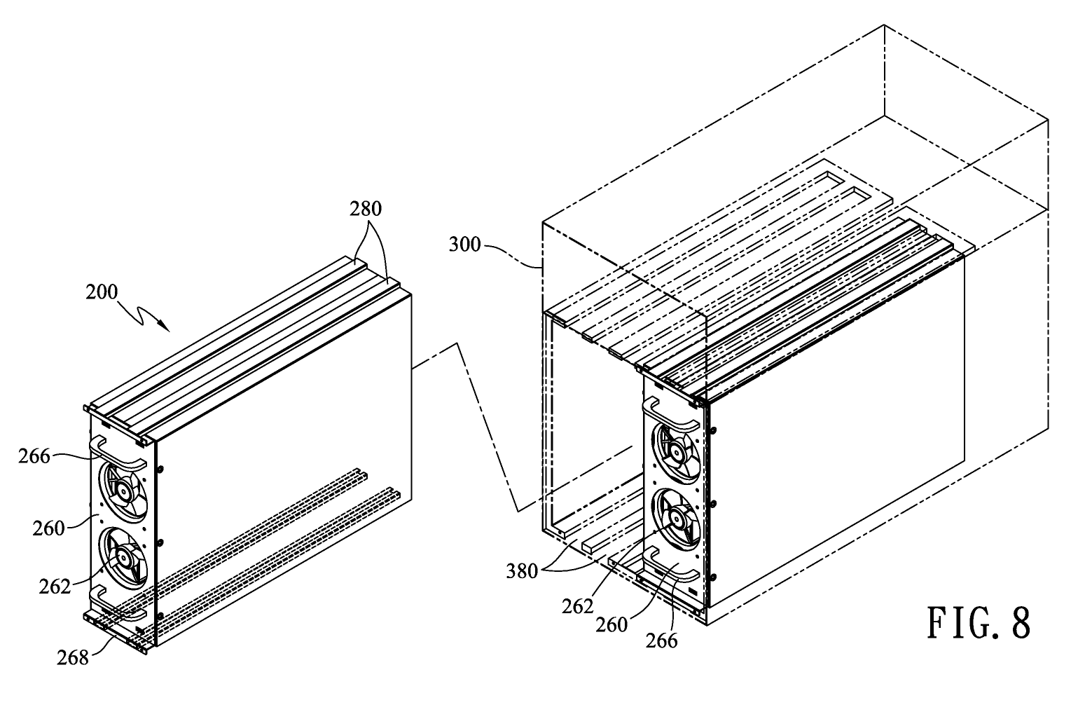

Please refer to FIGS. 2 and 3. An openable dual-board case for multi-mainboard system according to the present invention includes a generally rectangular tubular body 200, which is assembled from two bent plates 210 pivotally connected via at least one pivoting structure 230 to define two open ends 220, 222. The tubular body 200 may be mounted in a computer case 300 for a multi-mainboard system as shown in FIG. 8.

Each of the bent plates 210 has four sides, namely, a first open side 210a, a second open side 210b, a pivoting side 210c, and a joining side 210d. Wherein, the first and the second open side 210a, 210b are opposite to each other, while the pivoting and the joining side 210c, 210d are opposite to each other.

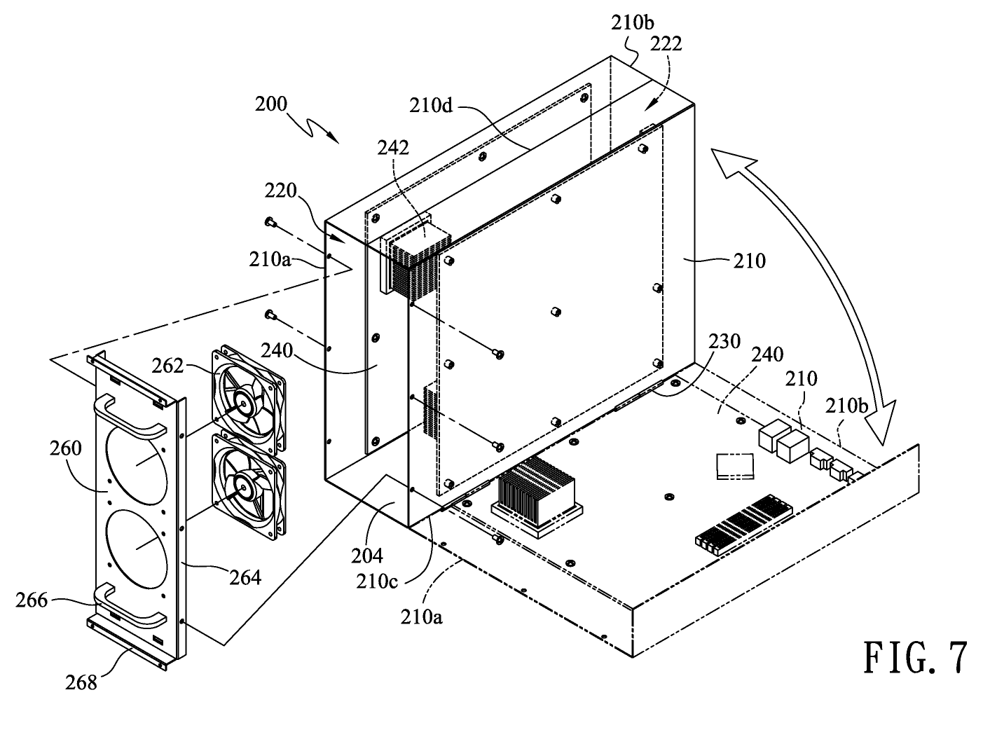

The two open ends 220, 222 of the tubular body 200 are located at the opposite first and second open sides 210a, 210b of the two bent plates 210, respectively. More specifically, the open end 220 is located at the first open sides 210a of the two bent plates 210, and the open end 222 at the second open sides 210b of the two bent plates 210, as shown in FIG. 7.

The pivoting structure 230 is located at the pivoting sides 210c of the two bent plates 210. A user may turn the two bent plates 210 about the pivoting structure 230 relative to each other, so as to connect or separate the joining sides 210d of the two bent plates 210 to or from each other. Each pivoting structure 230 includes several pivot holders 232 provided on the bent plates 210 at the pivoting sides 210c, and at least one pivot pin 234 received in the pivot holders 232, so that the two bent plates 210 are pivotally connected by and turnable about the pivot pin 232 relative to each other to open or close the tubular body 200. Herein, the pivot holders 232 may be independent elements screwed to the bent plates 210, or integrally formed on the bent plates 210 by curving some portions of the bent plates 210 outward extended from the pivoting sides 210c.

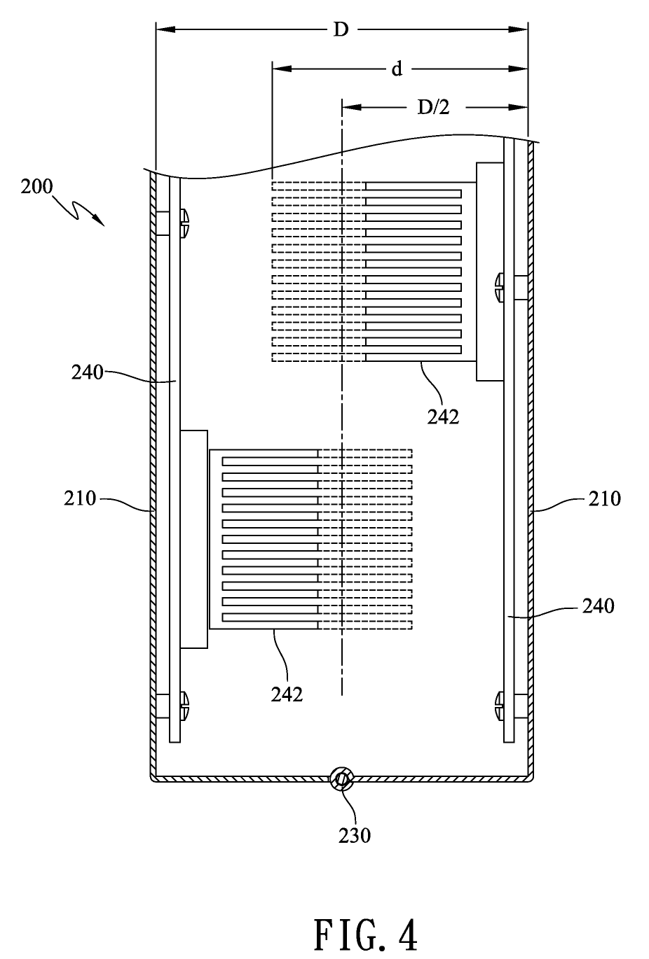

One or more mainboards 240 are mounted to the two bent plates 210 on their respective interiors that face each other. As an example, when there are two mainboards 240 being separately mounted on the two facing inner surfaces of the two bent plates 210, the two mainboards 240 are oriented to face each other with an integral and relatively large airflow passage formed therebetween. Please refer to FIG. 4. Radiation fins 242 are mounted on heat-producing elements, such as processors, on the mainboards 240 to locate near one of the two open ends 220, 222 of the tubular body 200. That is, the radiation fins 242 are located between the two facing interiors of the two bent plates 210. The processors or other heat-producing elements on the two facing mainboards 240 are staggered. Therefore, the radiation fins 242 mounted on the processors and other heat-producing elements on the two mainboards 240 are staggered, too. In this manner, a distance D between the two facing interiors of the bent plates 210 may be shortened to reduce an overall volume of the tubular body 200, or the radiation fins 242 may have an extended size. More specifically, a top of the radiation fins 242 may be located beyond a centerline of the tubular body 200. In other words, a distance d between the top of the radiation fins 242 on a mainboard 240 and the interior of the bent plate 210 having the same mainboard 240 mounted thereto is larger than or equal to one half of the distance D. Therefore, it is possible to enhance the heat-dissipation effect of the openable dual-board case of the present invention by increasing the size of the radiation fins 242 without increasing the size of the whole tubular body 200. On the other hand, the staggered processors, heat-producing elements, and radiation fins 242 also provide the possibility of reducing the volume of the tubular body 200, enabling the openable dual-board case of the present invention to have a volume even smaller than that of the conventional personal supercomputer with a plurality of parallelly arranged mainboards oriented to the same direction.

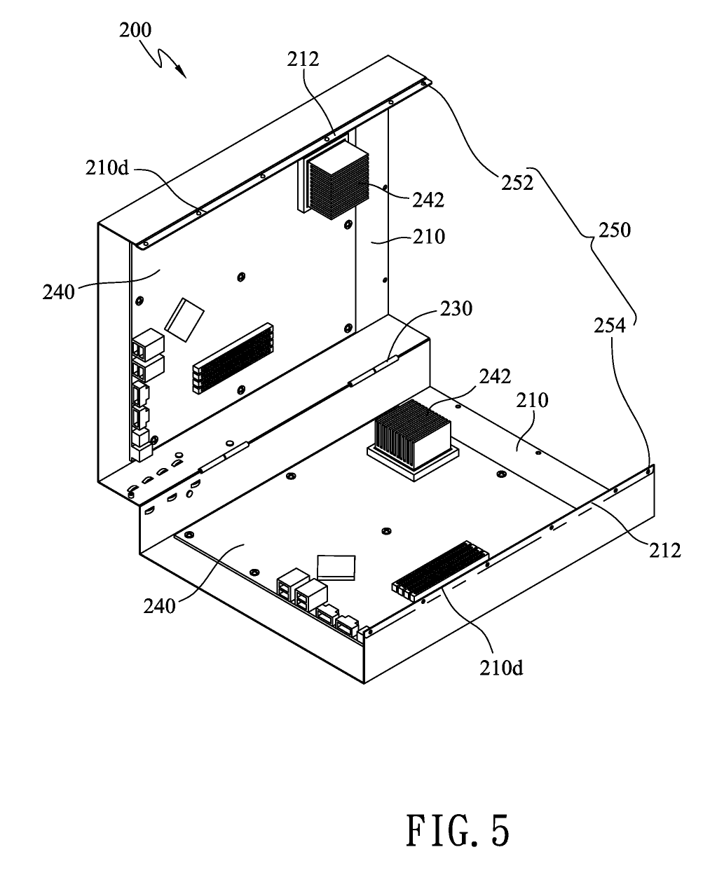

As shown in FIG. 5, a fastening structure 250 may be further provided on the bent plates 210 at the joining sides 210d to openably hold the two joining sides 210d and accordingly, the two bent plates in a closed position.

Each of the two bent plates 210 may further include an overlapping section 212 located at the joining side 210d of the bent plate 210. When the two bent plates 210 are pivotally turned to close the tubular body 200, the two overlapping sections 212 overlap each other. And, the fastening structure 250 is formed on the overlapping sections 212.

The fastening structure 250 includes at least one protrusion 252 and at least one recess 254 separately and correspondingly provided on the two overlapping sections 212. In other words, the protrusion 252 is located at one of the two overlapping sections 212, while the recess 254 corresponding thereto is located at the other overlapping section 212. Therefore, when the two bent plates 210 are pivotally turned to overlap the two overlapping sections 212, the protrusion 252 is tightly engaged with the recess 254 to firmly close the two bent plates 210 to form the tubular body 200.

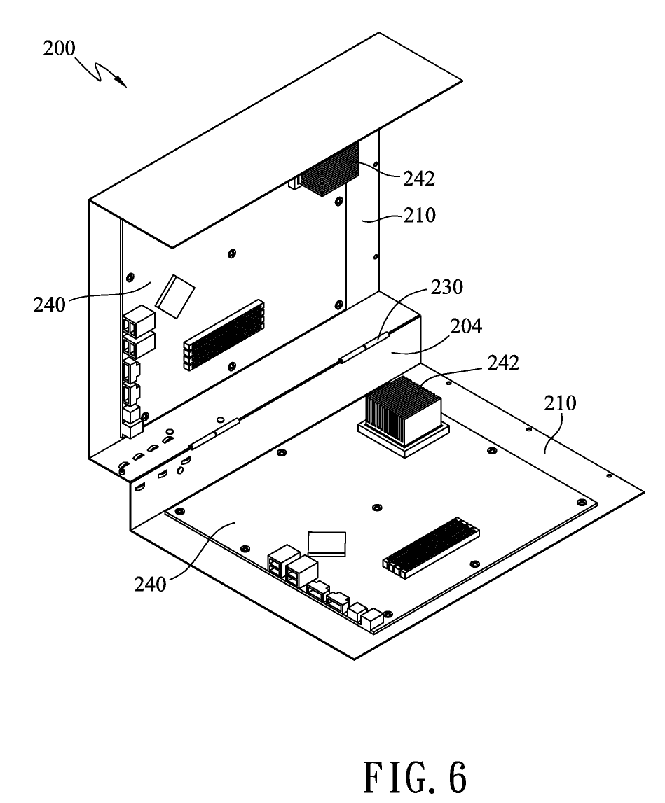

The tubular body 200 defines an inner space communicating with the two open ends 220, 222, so that airflow may flow through the inner space of the tubular body 200 to carry away heat produced by heat sources on the two mainboards 240 in the tubular body 200. Since the two mainboards 240 are mounted in the tubular body 200 face to face, allowing the inner space of the tubular body 20 to form an integral and relatively large airflow passage without being split and hindered by the mainboards 240 and other related elements thereon, such as radiating modules, so that noises produced during operation of heat-producing elements on the mainboards 240 may be largely reduced. Since the integral large airflow passage between the two face-to-face mainboards 240 allows airflow to quickly flow therethrough, enhanced heat-dissipation efficiency may be obtained. Moreover, since the two bent plates 210 may be pivotally turned relative to each other to thereby open the tubular body 200, a user may conveniently and efficiently proceed with necessary system assembling, dismounting, maintaining, and/or repairing.

Wherein, the two bent plates 210 may be two U-shaped plates. Alternatively, the two bent plates 210 may include one U-shaped plate and one L-shaped plate, as shown in FIG. 6.

Please refer to FIG. 7. The tubular body 200 may be provided at one of the open ends 220, 222 with a substantially rectangular cover plate 260 corresponding to a cross section of the tubular body 200. In the preferred embodiment of the present invention illustrated FIG. 7, the cover plate 260 is located at the open end 220 of the tubular body 200. And, a plurality of fan vents may be formed on the cover plate 260. In this case, the two bent plates 210 include one U-shaped plate having two bent walls and one L-shaped plate having only one bent wall, and the pivoting structure 230 may be mounted on the U-shaped plate 210 at one of the two bent walls thereof.

On an interior of the cover plate 260 facing toward the tubular body 200, several cooling fans 262 are mounted corresponding to the fan vents to assist in smooth flowing of cooling airflow in the tubular body 200. Since the tubular body 200 provides integral and relatively large airflow passage, the problems of turbulences, whooshing sound, and noise caused by operating fans as occurred in the split airflow passage in the conventional computer case 100 can be largely reduced. Moreover, cooling fans 262 with increased size may be used in the tubular body 200 to supply sufficient air flow and air pressure at low rotary speed without producing too much noise. In this case, the radiation fins 242 on the heat-producing elements, such as processors, mounted on the mainboards 240 are provided closer to the open end 220 of the tubular body 200, so as to enhance the heat-dissipation effect of the cooling fans 262.

The cover plate 260 includes one or more mounting sections 264 that are rearward extended from two lateral edges or other suitable positions of a main body of the cover plate 260, so that an angle about 90 degrees is contained between the mounting sections 264 and the main body of the cover plate 260. The cover plate 260 may be connected to the open end 220 of the tubular body 200 by fitting the mounting sections 264 around an exterior of the open end 220, so that the two bent plates 210 are stably connected and closed to each other. That is, with the cover plate 260 fitted around the open end 220, the tubular body 200 is prevented from opening automatically. Alternatively, the cover plate 260 may be connected to the open end 220 of the tubular body 200 by screwing the mounting sections 264 to the first open sides 210a of the two bent plates 210.

The cover plate 260 may be provided on an exterior with handles 266 to enable easy displacement of the openable dual-board case. The handles 266 may be U-shaped as shown in FIG. 7, or L-shaped, or any other suitable shapes that allow a user to grip at conveniently.

The cover plate 260 is also formed at an upper and/or a lower edge with one or more substantially L-shaped fixing sections 268. Each of the L-shaped fixing sections 268 has a horizontally portion outward extended from the upper and/or the lower edge of the cover plate 260 for fixing to an external mechanism, such as the computer case 300 of a multi-mainboard system shown in FIG. 8.

Please refer to FIG. 8. The tubular body 200 may be externally provided at a top and/or a bottom wall with locating rails 280 extended between the two open ends 220, 222 of the tubular body 200. The locating rails 280 are corresponding to channels 380 formed on a case of an external mechanism to movably associate with the channels 380. In the illustrated embodiment in FIG. 8, the case of the external mechanism is a computer case 300 of a multi-mainboard system. The locating rails 280 may be a narrow and elongate member formed by bending a flat plate, and have reduced terminal ends to provide good guiding function.

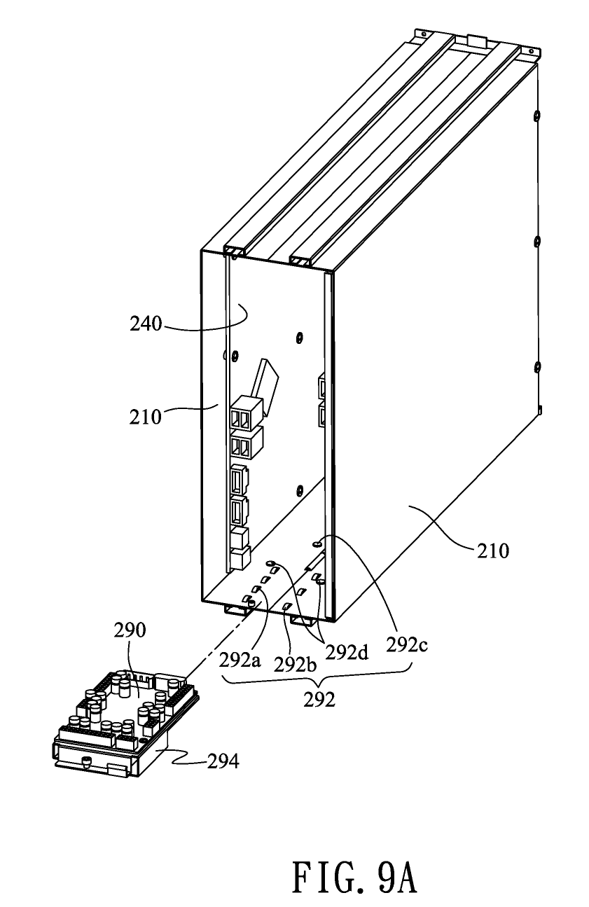

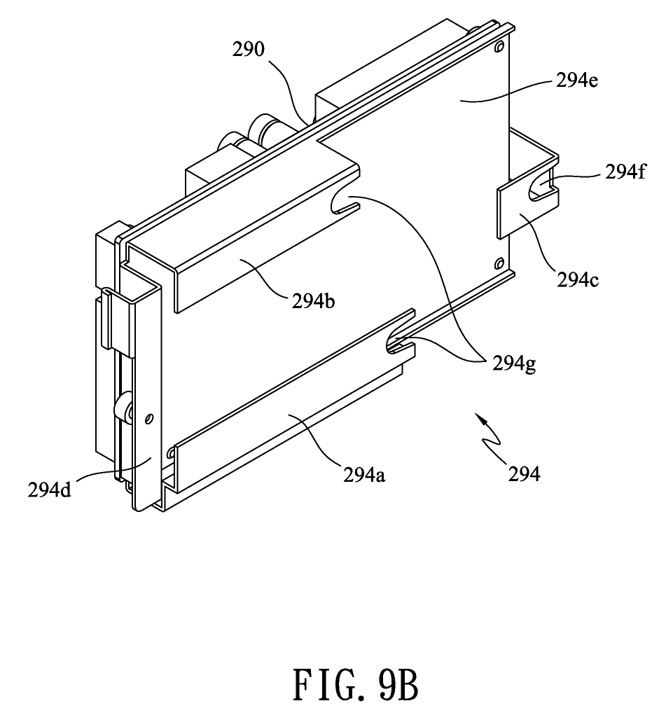

Since the tubular body 200 provides an integral and relatively large inner space, a power distribution board 290 for the openable dual-board case may also be mounted in the tubular body 200, that is, on an interior of the bent plates 210, as shown in FIG. 9A. For this purpose, the tubular body 200 is provided on an interior of the bottom wall at a predetermined position with a locating unit 292, and the power distribution board 290 is mounted on a top of a carrier 294, which is connected at an underside to the locating unit 292.

The locating unit 292 may include two guide ways 292a, 292b, each of which includes a row of upward protrusions formed by inward stamping the bottom wall of the tubular body 200, and one or more locating blocks 192c, 292d. Please refer to FIG. 9B. The carrier 294 includes a flat main body 294e, two substantially L-shaped or step-shaped sliding rails 294a, 294b, a stop element 294c, and a mounting section 294d. The L-shaped sliding rails 294a, 294b are connected at respective vertical portions to lower lateral sides of the main body 294e with respective horizontal portions flatly contacting with the interior of the bottom wall of the tubular body 200 adjacent to the guide ways 292a, 292b, so that the carrier 294 is connected to and movable along the guide ways 292a, 292b in the tubular body 200. The stop element 294c is a substantially L-shaped or step-shaped member with an upper end connected to a front edge of the main body 294e of the carrier 294. A pre-cut opening 294f is formed at the corner of the L-shaped stop element 294c for detachably engaging with the locating block 292c, so as to define a final position to which the carrier 294 may be slid into the tubular body 200 along the guide ways 292a, 292b. When the carrier 294 has been fully slid into the tubular body 200, the mounting section 294d located at a rear end of the carrier 294 is screwed to the tubular body 200, so that the carrier 294 is fixedly connected to the tubular body 200. Moreover, the sliding rails 294a, 294b are provided on respective horizontal portions at an end closer to the stop element 294c with a recess 294g each for detachably engaging with the locating blocks 292d, so as to further limit the position of the carrier 294 in the tubular body 200.

The present invention has been described with some preferred embodiments thereof and it is understood that many changes and modifications in the described embodiments can be carried out without departing from the scope and the spirit of the invention that is intended to be limited only by the appended claims.

What is claimed is:

1. An openable dual-board case for multi-mainboard system, comprising a substantially rectangular tubular body; the tubular body comprising:
two bent plates, each of which having a first and a second open side opposite to each other, and a pivoting and a joining side opposite to each other;
two open ends separately located at the first open sides and the second open sides of the bent plates; and
at least one pivoting structure provided at the pivoting sides of the bent plates, so that the two bent plates are pivotally connected by the pivoting structure and turnable about the pivoting structure relative to each other to join or separate the joining sides on the bent plates to or from each other.

2. The openable dual-board case of claim 1, wherein the tubular body further comprising a fastening structure provided at the joining sides of the bent plates for detachably holding the two joining sides together.

3. The openable dual-board case of claim 2, wherein each of the bent plates further includes an overlapping section provided at the joining side; the overlapping sections on the bent plates overlapping each other when the bent plates are pivotally turned about the pivoting structure to close to each other; and the fastening structure being provided on the overlapping sections.

4. The openable dual-board case of claim 3, wherein the fastening structure includes at least one protrusion located at the overlapping section on one of the bent plates, and at least one recess located at the overlapping section on the other bent plate corresponding to the protrusion.

5. The openable dual-board case of claim 1, wherein the pivoting structure includes a plurality of pivot holders provided on the bent plates at the pivoting sides, and at least one pivot pin received in the pivot holders.

6. The openable dual-board case of claim 1, wherein each of the bent plates is U-shaped.

7. The openable dual-board case of claim 1, wherein one of the bent plates is U-shaped and the other one of the bent plates is L-shaped.

8. The openable dual-board case of claim 1, further comprising at least one substantially rectangular cover plate for mounting to one of the open ends of the tubular body; and the cover plate being provided with a plurality of fan vents.

9. The openable dual-board case of claim 8, wherein the cover plate includes at least one mounting section perpendicularly rearward extended from the cover plate for connecting to one of the first and the second open sides of the bent plates.

10. The openable dual-board case of claim 8, wherein the cover plate includes at least one fixing section being substantially L-shaped and formed along at least one of an upper and a lower edge of the cover plate; and the fixing section having a horizontally portion outward extended from one of the upper and the lower edge of the cover plate.

11. The openable dual-board case of claim 8, wherein the cover plate includes at least one handle.

12. The openable dual-board case of claim 1, further comprising at least one mainboard mounted on an interior of each of the bent plates

13. The openable dual-board case of claim 12, wherein the mainboard mounted on each of the bent plates includes at least one radiation fin, and a distance from a top of the radiation fin on the mainboard to the interior of the bent plate on which the mainboard is mounted is larger than or equal to one half of a distance between the interiors of the bent plates.

14. The openable dual-board case of claim 1, wherein the tubular body further including a locating unit provided at a predetermined position on an interior of the two bent plates corresponding to a bottom wall of the tubular body; and a carrier having a top for carrying a power distribution board thereon, and an underside provided corresponding to the locating unit with at least one sliding rail, at least one stop element, and at least one mounting section for engaging with the locating unit.

15. The openable dual-board case of claim 1, wherein the tubular body further including at least one locating rail provided on an exterior of the bent plates to extend between the two open ends of the tubular body.

16. The openable dual-board case of claim 15, wherein the locating rail is a narrow and elongate member formed by bending a plate, and has at least one reduced end.
